(19) United States
(12) Patent Application Publication
(10) Pub. No.: US 2010/0081293 A1
(43) Pub. Date: Apr. 1, 2010

(54) METHODS FOR FORMING SILICON NITRIDE BASED FILM OR SILICON CARBON BASED FILM

(75) Inventors: ABHIJIT BASU MALLICK, Palo Alto, CA (US); Srinivas D. Nemani, Sunnyvale, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/243,375

(22) Filed: Oct. 1, 2008

(51) Int. Cl. H01L 21/31

(52) U.S. Cl. 438/794; 438/791; 257/E21.24

(57) ABSTRACT

A method for depositing a silicon nitride based dielectric layer is provided. The method includes introducing a silicon precursor and a radical nitrogen precursor to a deposition chamber. The silicon precursor has a N—Si—H bond, N—Si—Si bond and/or Si—Si—H bond. The radical nitrogen precursor is substantially free from included oxygen. The radical nitrogen precursor is generated outside the deposition chamber. The silicon precursor and the radical nitrogen precursor interact to form the silicon nitride based dielectric layer.

### BACKGROUND OF THE INVENTION

Semiconductor device geometries have dramatically decreased in size since their introduction several decades ago. Modern semiconductor fabrication equipment routinely produces devices with 250 nm, 180 nm, and 65 nm feature sizes, and new equipment is being developed and implemented to make devices with even smaller geometries. The smaller sizes, however, mean device elements have to work closer together which can increase the chances of electrical interference, including cross-talk and parasitic capacitance.

To reduce the degree of electrical interference, dielectric insulating materials are used to fill the gaps, trenches, and other spaces between the device elements, metal lines, and other device features. The dielectric materials are chosen for their ease of formation in the spaces between device features, and their low dielectric constants (i.e., “k-values”). Dielectrics with lower k-values are better at minimizing cross-talk and RC time delays, as well as reducing the overall power consumption of the device. Conventional dielectric materials include silicon oxide, which has an average k-value between 4.0 and 4.2 when deposited with conventional CVD techniques.

While the k-value of conventional CVD silicon oxide is acceptable for many device structures, the ever decreasing sizes and increasing densities of device elements have kept semiconductor manufacturers looking for dielectric materials with lower k-values. One approach has been to dope the silicon oxide with fluorine to make a fluorine-doped silicon oxide film (i.e., “FSG” film) with a dielectric constant as low as about 3.4 to about 3.6. Another has been the development of spin-on glass techniques that coat the substrate with highly flowable precursors like hydrogen silsesquioxane (HSQ) to form a porous low-k film.

Further more, silicon nitride films and silicon carbide films have also been used for electrical isolation in various semiconductor structures, such as shallow trench isolations, metal layer interconnects or other semiconductor structures. Silicon nitride films and silicon carbide films can be formed by CVD techniques. Conventional silicon nitride films and silicon carbide films are formed at a high temperature, such as 550° C. The 550° C. CVD process carries a thermal budget that can adversely affect wells and/or dopant region profiles formed within the semiconductor structures.

Accordingly, improvements to existing methods of depositing silicon nitrogen based films or silicon carbon based films are desirable.

### BRIEF SUMMARY OF THE INVENTION

Embodiments of the present invention pertain to methods that provide benefits over previously known processes employing a remote plasma system (RPS) to generate a radical nitrogen-containing precursor and/or a radical inert gas precursor to interact with an organo-silicon and/or silicon precursor under a low process temperature, such as about 100° C. or less, to form a silicon nitride based dielectric layer or a silicon carbon based layer. For example, the silicon precursor used for forming a silicon nitride based layer has a N—Si—H bond, N—Si—Si bond and/or Si—H bond. The organo-silicon precursor used for forming a silicon carbon based layer has a C—Si—H bond and/or C—Si—Si bond. Since the radical nitrogen-containing precursor and/or the radical inert gas precursor are substantially free from included oxygen, the methods can desirably form a silicon nitride based layer or a silicon carbon based layer.

One embodiment provides a method for depositing a silicon nitride based dielectric layer. The method includes introducing a silicon precursor and a radical nitrogen precursor to a deposition chamber. The silicon precursor has a N—Si—H bond, N—Si—Si bond and/or Si—Si—H bond. The radical nitrogen precursor is substantially free from included oxygen. The radical nitrogen precursor is generated outside the deposition chamber. The silicon precursor and the radical nitrogen precursor interact to form the silicon nitride based dielectric layer.

Another embodiment provides a method for depositing a silicon nitride based dielectric layer. The method includes introducing a silicon precursor and a radical nitrogen precursor to a deposition chamber. The silicon precursor has a formula SiHₙX₄₋ₙ, n is a number of 1-4 and X is a halogen. The silicon precursor has a Si—H bond which is weaker then a Si—X bond. The radical nitrogen precursor is substantially free from included oxygen. The radical nitrogen precursor is generated outside the deposition chamber. The silicon precursor and the radical nitrogen precursor interact to form the silicon nitride based dielectric layer.

Another embodiment provides a method for depositing a silicon carbon based dielectric layer. The method includes introducing an organo-silicon precursor and a radical inert gas precursor to a deposition chamber. The organo-silicon precursor has a bond selected from the group consisting of C—Si—H bond and C—Si—Si bond. The radical inert gas precursor is substantially free from included oxygen. The radical inert gas precursor is generated outside the deposition chamber. The organo-silicon precursor and the radical inert gas precursor interact to form the silicon carbon based dielectric layer.

These and other embodiments of the invention along with many of its advantages and features are described in more detail in conjunction with the text below and attached figures It should be understood, however, that the invention is not limited to the precise arrangements and instrumentalities shown.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flow chart illustrating an exemplary method for forming a silicon nitride based dielectric layer over a substrate according to the present invention;

FIG. 2 is a flow chart illustrating an exemplary method for forming a silicon carbon based dielectric layer over a substrate according to the present invention; and

FIG. 3 is a schematic cross-sectional view of an exemplary process system of the present invention.

### DETAILED DESCRIPTION OF THE INVENTION

The present invention relates to methods for forming a silicon nitride based dielectric layer or a silicon carbon based dielectric layer. In embodiments, the methods use a remote plasma system (RPS) to generate a radical nitrogen-containing precursor and/or a radical inert gas precursor to interact with an organo-silicon and/or a silicon precursor under a low process temperature, such as about 100° C. or less, to form a silicon nitride based dielectric layer or a silicon carbon based dielectric layer. The silicon precursor used for forming a silicon nitride based dielectric layer has a N—Si—H bond, N—Si—Si bond and/or Si—H bond. The organo-silicon precursor used for forming a silicon carbon based dielectric layer has a C—Si—H bond and/or C—Si—Si bond. With weak and/or unstable bonding of Si—H or Si—Si, radical Si can be formed and interact with racial nitrogen or radical carbon to form Si—N or Si—C bonding so as to form a silicon nitride based or a silicon carbon based dielectric layer. In addition, the radical nitrogen-containing precursor and/or the radical inert gas precursor can be substantially free from included oxygen, the methods can desirably form a silicon nitride based or a silicon carbon based dielectric layer.

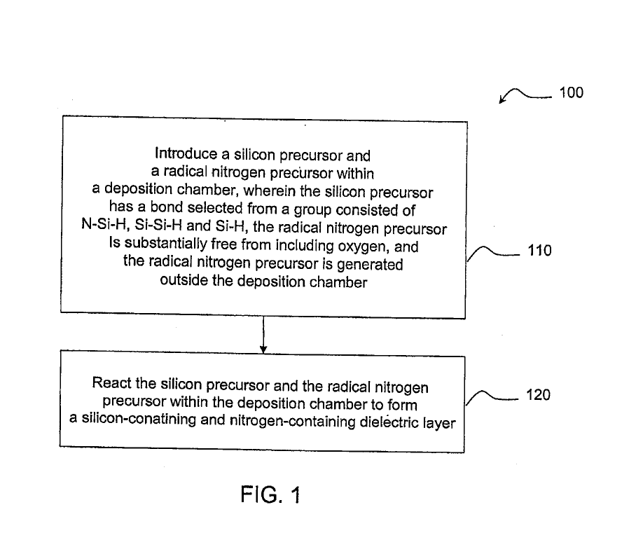

FIG. 1 is a flow chart illustrating an exemplary method for forming a silicon nitride based dielectric layer over a substrate according to the present invention. Exemplary method 100 includes a non-exhaustive series of steps to which additional steps (not shown) may also be added. One of ordinary skill in the art would recognize many variations, modifications, and alternatives. In embodiments, method 100 can include introducing a silicon precursor and a radical nitrogen precursor within a deposition chamber, wherein the silicon precursor has a bond selected from a group consisting of N—Si—H, N—Si—Si, and Si—H, the radical nitrogen precursor is substantially free from included oxygen elements, and the radical nitrogen precursor is generated outside the deposition chamber (process 110). The silicon precursor and the radical nitrogen precursor interact within the deposition chamber to form a silicon-containing and nitrogen-containing dielectric layer (process 120). The silicon nitride based dielectric layer can be a silicon nitride layer or a silicon oxynitride layer, for example. In embodiments, a silicon precursor and a radical nitrogen precursor interact within a deposition chamber, wherein the silicon precursor has a formula SiHₙX₄₋ₙ, wherein n is a number of 1-4, X is a halogen, and the silicon precursor has a Si—H bond which is weaker then a Si—X bond.

The silicon precursor has a bond selected from a group consisting of N—Si—H, N—Si—Si, and Si—H. For example, the silicon precursor can be silane, linear polysilanes (disilane, trisilane and higher homologs), cyclic polysilanes (such as cyclopentasilane and ladder polysilane), diaminosilanes (where R1 and R2 are alkyl groups such as methyl, ethyl, and higher homologs and/or hydrogen), trisilylamines (where R is alkyl group such as methyl, ethyl, and higher homologs and/or hydrogen), trisilylamine, N(SiH₃)₃:

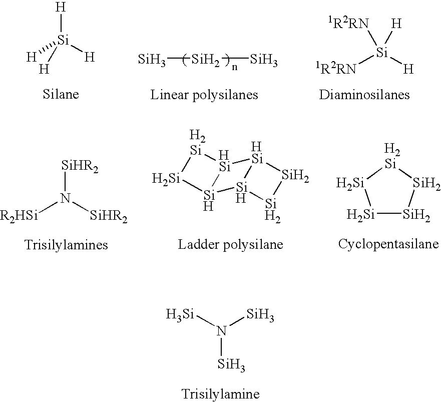

In embodiments, the silicon precursor can be mixed with a carrier gas before or during its introduction to the deposition chamber. A carrier gas can be an inactive gas that does not undesirably interfere with the formation of the silicon nitride layer or the silicon oxynitride layer. Examples of carrier gases can include helium, neon, argon, and hydrogen, among other gases. For example, the silicon precursor may be introduced to the deposition chamber by mixing a silicon compound (gas or liquid) with helium at a flow rate of about 600 to about 2400 sccm through the room-temperature silicon precursor to provide a flow of the precursor to the chamber at a rate of about 800 mgm to about 1600 mgm.

The radical nitrogen precursor can be generated outside the deposition chamber. For example, the radical nitrogen precursor can be generated in a remote plasma generating system (RPS) that generates reactive species by exposing a more stable starting material to the plasma. For example, the starting material can be a mixture that includes molecular ammonia (NH₃) and/or nitrogen (N₂). The exposure of this starting material to a plasma from the RPS causes a portion of the molecular ammonia to dissociate into radicals N, NH and/or NH₂, a highly reactive radical species that can desirably replace Si—Si and/or Si—H bonds of a silicon precursor at a temperature between about −10° C. and about 100° C. to form a flowable dielectric on the substrate surface. Since the radical nitrogen precursor is substantially free from included oxygen, the method can desirably form a silicon nitride based dielectric layer. In embodiments, the nitrogen precursor is NH₃, but not NOx.

The radical nitrogen precursor can be, for example, N, NH and/or NH₂, as well as other radical nitrogen precursor and combinations of precursors. Radicals N, NH, and/or NH₂ are reactive to attack Si—H and/or Si—Si bonds which are unstable and weak bonding. Radicals N, NH, and/or NH₂ then bond with Si radicals to form Si—N, Si—NH and/or Si—NH₂ bonds which are more stable than Si—H and Si—Si bonds. By forming Si—N, Si—NH and/or Si—NH₂ bonds, a silicon nitride based layer or a silicon oxynitride based layer can be desirably deposited over a substrate. In embodiments, a radical inert gas precursor, such as Ar, Krypton (Kr), and/or Xenon (Xe), is introduced into the deposition chamber to bombard Si—H and/or Si—Si bonds to break Si—H and/or Si—Si bonds and form Si radicals. The Si radicals are reactive to radicals N, NH and/or NH₂ to form Si—N, Si—NH and/or Si—NH₂ bonds. Accordingly, the radical inert gas precursor can desirably help the silicon precursor and the radical nitrogen-containing precursor to form a silicon nitride layer or a silicon oxynitride layer deposited over a substrate.

In embodiments, method 100 is free from an anneal process within any oxygen-containing environment that may convert a silicon nitride based film into a silicon oxide based film. For example, method 100 is free from a steam anneal process that may convert a silicon nitride based film into a silicon oxide based film. By free from an oxygen-containing anneal process, the silicon nitride based film can be desirably achieved.

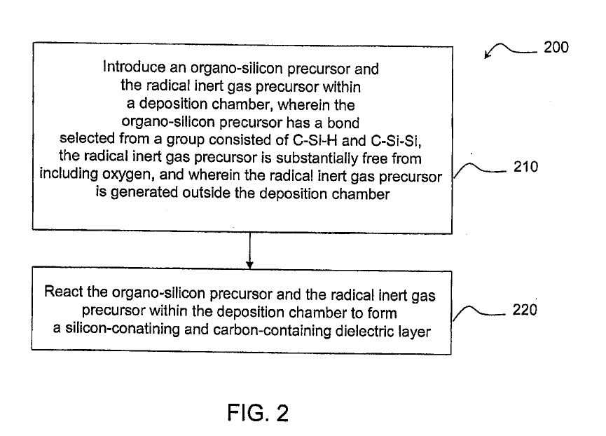

FIG. 2 is a flow chart illustrating an exemplary method for forming a silicon carbon based dielectric layer over a substrate according to the present invention. Exemplary method 200 includes a non-exhaustive series of steps to which additional steps (not shown) may also be added. One of ordinary skill in the art would recognize many variations, modifications, and alternatives. In embodiments, method 200 can include introducing an organo-silicon precursor and a radical inert gas precursor within a deposition chamber, wherein the organo-silicon precursor has a bond selected from a group consisting of C—Si—H and C—Si—Si, the radical inert gas precursor is substantially free from included oxygen, and the radical inert gas precursor is generated outside the deposition chamber (process 210). In embodiments, the radical inert gas precursor does not have an oxygen group. The organo-silicon precursor and the radical inert gas precursor interact within the deposition chamber to form a silicon carbon based dielectric layer (process 220). The silicon carbon based dielectric layer can be a silicon carbide (SiC) layer, a silicon oxycarbide (SiOC) layer, or a silicon carbon-nitride (SiCN) layer, for example.

The organo-silicon precursor has a bond selected from a group consisting of C—Si—H, C—Si—Si. For example, the organo-silicon precursor for forming a silicon carbon (SiC) film can be alkylsilanes (where R is alkyl group such as methyl, ethyl, and higher homologs and/or hydrogen), bridged alkylsilanes (where R is alkyl group such as methyl, ethyl, and higher homologs and/or hydrogen), cyclic alkysilanes (where R is alkyl group such as methyl, ethyl, and higher homologs and/or hydrogen), and/or cyclic alkyldisilanes (where R1 and R2 are alkyl group such as methyl, ethyl, and higher homologs). For embodiments forming a silicon oxycarbide (SiOC), the organo-silicon precursor can be, for example, linear polyalkoxysilanes (where R is alkoxy group such as methoxy, ethoxy and higher homologs), cyclic alkoxydisilanes (where R1 and R2 are alkoxy groups such as methoxy, ethoxy and higher homologs), alkoxysilanes (where R is alkoxy group such as methoxy, ethoxy and higher homologs), alkoxydisilanes (where R1 and R2 are alkoxy groups such as methoxy, ethoxy and higher homologs), and/or polyaminosilanes (where R is alkoxy group such as methoxy, ethoxy and higher homologs). For embodiments forming a silicon carbon nitride (SiCN) film, the organo-silicon precursor can be, for example, cyclic alkylaminosilanes (where R is alkyl group such as methyl, ethyl, and higher homologs and/or hydrogen), triaminosilanes (where R1 and R2 are alkyl group such as methyl, ethyl, and higher homologs), diaminosilanes (where R1 and R2 are alkyl group such as methyl, ethyl, and higher homologs), and/or trisilylamines (where R is alkyl group such as methyl, ethyl, and higher homologs).

### For SiC Films:

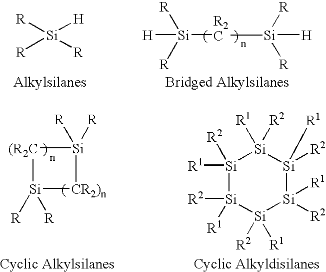

### For SiOC Films:

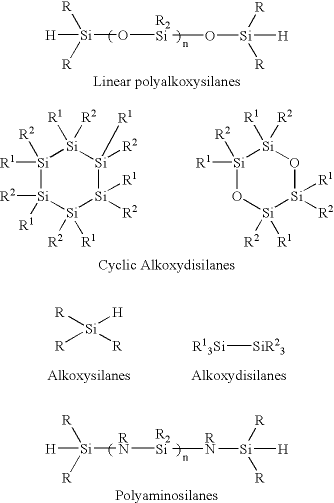

For SiCN films:

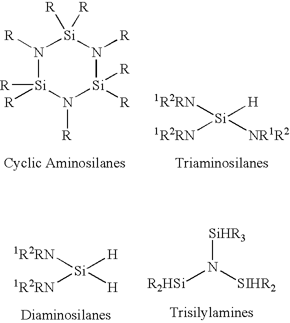

In embodiments, the organo-silicon precursor can be mixed with a carrier gas before or during its introduction to the deposition chamber. A carrier gas can be an inactive gas that is substantially free from interfering with the formation of the silicon carbon based dielectric layer. Examples of carrier gases can include helium, neon, argon, and hydrogen, among other gases. For example, the organo-silicon precursor may be introduced to the deposition chamber by mixing an organo-silicon compound (gas or liquid) with helium at a flow rate of about 600 to about 2400 sccm through the room-temperature organo-silicon precursor to provide a flow of the precursor to the chamber at a rate of about 800 mgm to about 1600 mgm.

The radical inert gas precursor can be generated outside the deposition chamber. For example, the radical inert gas precursor can be generated in a remote plasma generating system (RPS) that generates bombard species by exposing a more stable starting material to the plasma. For example, the starting material can be a gas including Ne, Ar, Kr and/or Xe. The exposure of this starting material to a plasma from the RPS causes a portion of the inert gas to dissociate into radicals Ne, Ar, Kr and/or Xe, a bombard specie that can desirably bombard Si—Si and/or Si—H bonds of an organo-silicon precursor to form radicals C—Si which are reactive to each other. In embodiments, radicals C—Si can interact at a temperature between about −10° C. and about 100° C. to form a flowable dielectric material over the substrate surface. Since the radical inert gas precursor is substantially free from included oxygen elements, the method can desirably form a silicon carbon based dielectric layer.

The radical inert gas precursor can be, for example, Ne, Ar, Kr and/or Xe, as well as other radical inert gas precursor and combinations of precursors. Radicals Ne, Ar, Kr, and/or Xe, are introduced into the deposition chamber to bombard Si—H and/or Si—Si bonds to break Si—H and/or Si—Si bonds and form C—Si radicals. C—Si radicals of the gas precursor are reactive to each other to form C—Si-Hi and/or C—Si—Si bonds. Accordingly, the radical inert gas precursor can desirably break Si—H and/or Si—Si bonds, such that the organo-silicon precursor radicals can interact to form a SiC layer, SiOC layer or a SiCN layer over a substrate.

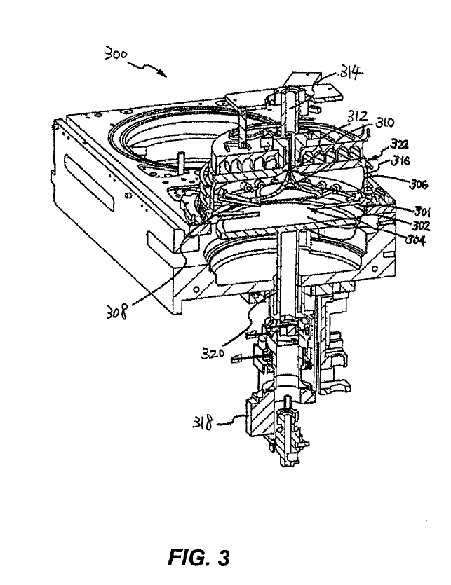

FIG. 3 is a schematic cross-sectional view of an exemplary process system of the present invention. In FIG. 3, system 300 includes a deposition chamber 301 where precursors chemically interact and deposit a flowable dielectric film over a substrate 302. Substrate 302 (e.g., a 200 mm, 300 mm, 400 mm, etc. diameter semiconductor substrate wafer) can be disposed over a rotatable substrate pedestal 304, which can be vertically translatable to position substrate 302 closer or further away from overlying precursor distribution system 306. Pedestal 304 can rotate substrate 302 at a rotational speed of about 1 rpm to about 2000 rpm (e.g., about 10 rpm to about 120 rpm). Pedestal 304 can vertically translate substrate 302 a distance from, for example, about 0.5 mm to about 100 mm from side nozzles 308 of precursor distribution system 306.

Precursor distribution system 306 includes a plurality of radially distributed side nozzles 308, each having one of two different lengths. In embodiments, side nozzles 308 can be optional to leave a ring of openings distributed around the wall of deposition chamber 301. The precursors can flow through these openings into chamber 301.

Precursor distribution system 306 can include conically-shaped top baffle 310 that may be coaxial with the center of substrate pedestal 304. Fluid channel 312 can run through the center of baffle 310 to supply a precursor or carrier gas with a different composition than the precursor flowing down the outside directing surface of baffle 310.

The outside surface of baffle 310 can be surrounded by conduit 314, which directs a reactive precursor from a reactive species generating system (not shown) that is positioned over deposition chamber 301. Conduit 314 can be a straight circular tube with one end opening coupled with the outside surface of baffle 310 and the opposite end coupled with the reactive species generating system (not labeled). The reactive species generating system can be a remote plasma generating system (RPS) that generates the reactive species by exposing a more stable starting material to the plasma. Because the reactive species generated in the reactive species generating system are often highly reactive with other deposition precursors at even room temperature, they can be transported in isolated gas mixture down conduit 314 and dispersed into reaction chamber 301 by baffle 310 before being mixed with other deposition precursors.

In embodiments, system 300 may also include RF coils (not shown) coiled around dome 316 of deposition chamber 301. These coils can create an inductively-coupled plasma in deposition chamber 301 to desirably enhance the reactivity of the reactive species precursor and other precursors to deposit the fluid dielectric film on the substrate. For example, a gas flow containing reactive radical nitrogen introduced into chamber 301 by baffle 310 and an organo-silicon precursor introduced from channel 312 and/or one or more of side nozzles 308 can interact above substrate 302 by the RF coils. The radical nitrogen and organo-silicon precursor rapidly interact in the plasma even at low temperature to form a flowable dielectric film on the surface of substrate 302.

The substrate surface itself may be rotated by pedestal 304 to desirably achieve the uniformity of the deposited film. The rotation plane may be parallel to the plane of the wafer deposition surface, or the two planes may be partially out of alignment. When the planes are out of alignment, the rotation of substrate 302 can create a wobble that can generate a fluid turbulence in the space above the deposition surface. In some circumstances, this turbulence may also desirably enhance the uniformity of the dielectric film deposited on the substrate surface. Pedestal 304 may also include recesses and/or other structures that create a vacuum chuck to hold the wafer in position on the pedestal as it moves. Typical deposition pressures in chamber 301 is from about 0.05 Torr to about 200 Torr total chamber pressure (e.g., 1 Torr), which makes a vacuum chuck feasible for holding the wafer in position.

Pedestal rotation may be actuated by motor 318, which is positioned below deposition chamber 301 and rotationally coupled to shaft 320, which supports pedestal 304. Shaft 320 can include internal channels (not shown) that carry cooling fluids and/or electrical wires from cooling/heating systems below deposition chamber 301 to pedestal 304. These channels can extend from the center to the periphery of pedestal 304 to provide uniform cooling and/or heating to substrate 302. They can be configured to operate when shaft 320 and substrate pedestal 304 are rotating and/or translating. For example, a cooling system can operate to keep the temperature of substrate 302 of about 100° C. or less during the deposition of the dielectric film while pedestal 304 is rotating.

System 300 can include irradiation system 322 positioned above dome 316. Lamps (not shown) from irradiation system 322 can irradiate substrate 302 to bake or anneal the deposited film over substrate 302. The lamps can be activated during the deposition to enhance a reaction in the film precursors or deposited film. At least the top portion of dome 316 is made from a translucent material capable of transmitting a portion of the light emitted from the lamps.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

As used herein and in the appended claims, the singular forms “a”, “and”, and “the” include plural referents unless the context clearly dictates otherwise. Thus, for example, reference to “a process” may includes a plurality of such processes and reference to “the nozzle” may include reference to one or more nozzles and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, or groups.

What is claimed is:

1. A method for depositing a silicon nitride based dielectric layer, the method comprising:
introducing a silicon precursor and a radical nitrogen precursor to a deposition chamber, wherein the silicon precursor has a bond selected from the group consisting of N—Si—H bond, N—Si—Si bond and Si—Si—H bond, the radical nitrogen precursor is substantially free from included oxygen, and the radical nitrogen precursor is generated outside the deposition chamber; and
interacting the silicon precursor and the radical nitrogen precursor to form the silicon nitride based dielectric layer.

2. The method of claim 1 wherein the silicon precursor is selected from the group consisting of linear polysilanes, diaminosilanes, trisilylamines, bis(diethylamino)silane, cyclopentasilane, N(SiH₃)₃, and/or ladder polysilanes.

3. The method of claim 1 wherein the radical nitrogen precursor is selected from the group consisting of N, NH, and NH₂.

4. The method of claim 1 further comprising a radical inert gas precursor.

5. The method of claim 4 wherein the radical inert gas precursor is radical argon (Ar).

6. The method of claim 1 wherein interacting the silicon precursor and the radical nitrogen precursor has a process temperature between about −10° C. and about 100° C.

7. The method of claim 1 wherein the silicon nitride based dielectric layer is a silicon nitride layer.

8. The method of claim 1 further comprising generating the radical nitrogen precursor in a remote process system.

9. A method for depositing a silicon nitride based dielectric layer, the method comprising:
introducing a silicon precursor and a radical nitrogen precursor to a deposition chamber, wherein the silicon precursor has a formula SiHₙX₄₋ₙ, n is a number of 1-4, X is a halogen, the silicon precursor has a Si—H bond which is weaker then a Si—X bond, the radical nitrogen precursor is substantially free from included oxygen, and the radical nitrogen precursor is generated outside the deposition chamber; and
interacting the silicon precursor and the radical nitrogen precursor to form the silicon nitride based dielectric layer.

10. The method of claim 9 wherein the silicon precursor is silane.

11. The method of claim 9 wherein the radical nitrogen precursor is selected from the group consisting of N, NH, and NH₂.

12. The method of claim 9 further comprising a radical inert gas precursor.

13. The method of claim 12 wherein the radical inert gas precursor is radical argon (Ar).

14. The method of claim 9 wherein interacting the silicon precursor and the radical nitrogen precursor has a process temperature between about −10° C. and about 100° C.

15. The method of claim 9 wherein the silicon nitride based dielectric layer is a silicon nitride layer.

16. The method of claim 9 further comprising generating the radical nitrogen precursor in a remote process system.

17. A method for depositing a silicon carbon based dielectric layer, the method comprising:
introducing an organo-silicon precursor and a radical inert gas precursor to a deposition chamber, wherein the organo-silicon precursor has a bond selected from the group consisting of C—Si—H bond and C—Si—Si bond, the radical inert gas precursor is substantially free from included oxygen, and the radical inert gas precursor is generated outside the deposition chamber; and
interacting the organo-silicon precursor and the radical inert gas precursor to form the silicon carbon based dielectric layer.

18. The method of claim 17 wherein the organo-silicon precursor is provided to form a silicon carbide (SiC) layer and selected from the group consisting of alkylsilanes, bridged alkylsilanes, cyclic alkysilanes, and cyclic alkyldisilanes.

19. The method of claim 17 wherein the organo-silicon precursor is provided to form a silicon oxycarbide (SiOC) layer and selected from the group consisting of linear polyalkylsilanes, cyclic alkoxydisilanes, alkoxysilanes, alkoxydisilanes, and polyaminosilanes.

20. The method of claim 17 wherein the organo-silicon precursor is provided to form a silicon carbon nitride (SiCN) layer and selected from the group consisting of cyclic aminosilanes, triaminosilanes, diaminosilanes, and/or trisilylamines.

21. The method of claim 17 wherein the radical inert gas precursor is radical argon (Ar).

22. The method of claim 17 wherein interacting the organo-silicon precursor and the radical inert gas precursor has a process temperature between about −10° C. and about 100° C.

23. The method of claim 17 wherein the silicon carbon based dielectric layer is a silicon carbide layer.

24. The method of claim 17 further comprising generating the radical inert gas precursor in a remote process system.
